(19) United States
(12) Patent Application Publication
(10) Pub. No.: US 2008/0117595 A1
(43) Pub. Date: May 22, 2008

(54) Operating Housing

(76) Inventor: Tim Kramer, Solms (DE)

Correspondence Address: PAULEY PETERSEN & ERICKSON, 2800 WEST HIGGINS ROAD, SUITE 365, HOFFMAN ESTATES, IL, 60195, US

(21) Appl. No.: 11/793,620

(22) PCT Filed: Mar. 3, 2006
(86) PCT No.: PCT/EP06/01932

§ 371 Date: Jun. 19, 2007

(30) Foreign Application Priority Data
Apr. 8, 2005 (DE) 10 2005 016 115.4

(51) Int. Cl. H05K 7/20; H02B 1/56

(52) U.S. Cl. 361/697; 454/184; 62/259.2; 361/689; 361/690; 361/702; 361/699

(57) ABSTRACT

An operating housing including four lateral walls, a front wall, and a rear wall, and a cooling device for carrying off dissipated heat from integrated electronic components. This invention provides an operating housing which has a compact structure and efficiently cools electronic components. Thus, the cooling device has a cooling plate through which a cooling liquid flows and which forms a largest part of a rear wall.

### BACKGROUND OF THE INVENTION

1. Field of the Invention

This invention relates to a control housing with four side walls, a front wall, a rear wall, and a cooling device for removing waste heat from installed electronic components.

2. Discussion of Related Art

A control housing, is known from RITTAL Manual 29, page 181 (1997), which is used by an operator for controlling devices and has various control elements on an exterior, in particular a front, and has at least one visual display, which is preferably designed as a flat display field of a computer installed in the interior. Besides the computer, which normally has a housing, further electrical and electronic components can be arranged in the interior. The control housing can be pivotably seated on a support arm and designed to be relatively compact.

### SUMMARY OF THE INVENTION

One object of this invention is to provide a control housing of the type mentioned above but with a compact arrangement, easy handling and operation, and as efficient as possible cooling of the built-in components.

This object is attained with a control housing having characteristics taught in the specification and in the claims. The cooling device has a cooling plate through which the coolant flows and which forms the largest portion of the rear wall. This design of the cooling device contributes to a flat, compact structure, wherein a high cooling output is assured.

An advantageous structure with simple mounting and a large cooling surface is possible if a circumferential edge area of the cooling plate is attached to wall sections which surround a rear opening of the control housing on the inside or the outside.

Simple manufacturing and dependable functioning without the danger of leakage of coolant in the interior is accomplished if at least one cooling channel is cut into the cooling plate for conducting coolant and has an inflow and an outflow connector arranged on the exterior of the rear wall.

Increased cooling output is achieved if at least one cooling body, which has cooling ribs or airflow channels, is formed as one piece on the inside of the cooling plate facing the interior of the control housing, or is applied as a separate part, through which the air charged with waste heat flows in an interior of the control housing.

Other measures can be advantageous for removing waste heat wherein at least one fan is arranged in the interior of the control housing, for transporting air charged with waste heat to the cooling plate or to the cooling body.

In one embodiment of the control housing in connection with an installed computer, a computer with a display field installed in the front wall is received in the control housing, which has a fan installed in the computer housing and which is brought into contact with the interior of the control housing for removing the air to the cooling plate or the cooling body. In this case, the computer housing itself has ventilating openings. The required class of protection results from the tightly encapsulated control housing.

Other measures are advantageous for efficient cooling wherein one or several air guidance vanes are applied to an interior of the control housing, by which the air charged with waste heat is guided along the inside of the cooling plate or over the cooling body.

Dependable functioning, as well as advantageous manufacturing options, result if at least one cooling channel has a line installed. This construction also makes possible manifold adaptation options to different circumstances.

In one advantageous manufacture, the line is pressed into at least one receiving conduit, which is machined from the flat side and extends in, a meander shape, and the respective flat side is subsequently flattened out.

### BRIEF DESCRIPTION OF THE DRAWINGS

This invention is explained in greater detail in view of exemplary embodiments, making reference to the drawings, wherein:

FIGS. 1A and 1B each shows a schematic view of a first embodiment of a control housing with a cooling plate, in a cross section and from the rear;

FIGS. 2A and 2B each shows a second embodiment of the control housing and a cooling body in cross section and from the rear;

FIG. 3 shows a schematic plan view of a cooling plate from the rear; and

FIG. 4 shows a cross section of sections of the cooling plate.

### DETAILED DESCRIPTION OF THE INVENTION

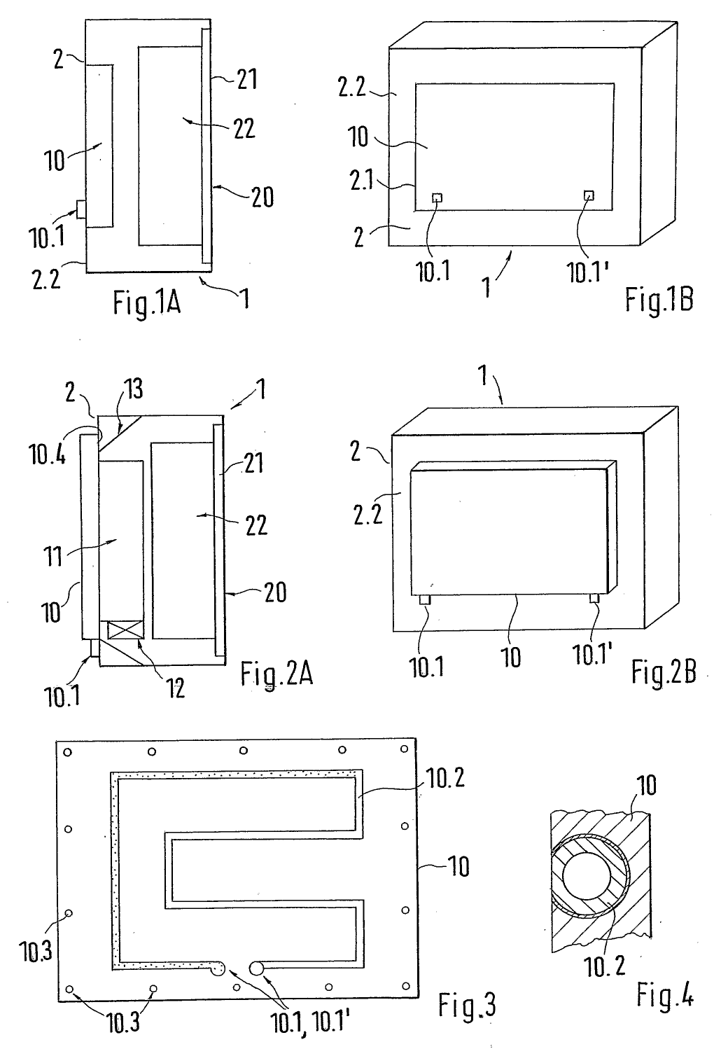

A control housing 1 with a rear wall 2 having a cooling plate 10 is shown in FIGS. 1A and 1B. The cooling plate 10 is applied to the rear wall 2 from the inside of the control housing 1 and only protrudes slightly into the interior of the control housing 1. On the outside, the rear wall 2 is flat, except for an inflow connector 10.1 and an outflow connector 10.1′. Here, the cooling plate 10 lies free on the outside, except for an edge area 10.4, which rests in a flange-like manner in wall sections 2.2 which surround a rear opening 2.1 on all sides, and is preferably fixed in place from the rear by screws which engage fastening holes 10.3, such as shown in FIG. 3, or threaded bores. Sealing means are applied between the edge area 10.4 of the cooling plate 10 and the wall sections 2.2 in order to obtain a high class of protection of the operating housing 1, which is advantageously completely encapsulated, except for possible application points for cables, or an attachment opening for a support arm. A built-in computer 20 with a relatively flat computer housing 22 is installed in the control housing 1 and has a large-surface display field 21 on the front of the control housing 1. The display field 21 is sealingly attached to an edge running around the front wall. Various manual control elements can be arranged on the front side, but in place thereof they can also be arranged or complement, for example, an additional control part attached to an underside of the control housing 1 and projecting toward the front. Still further electrical or electronic components can be housed in the control housing 1.

In the embodiment shown in FIGS. 2A and 2B, the cooling plate 10 is attached from the outside with an edge area 10.4 on the wall sections 2.2 and projects into the interior of the control housing 1 with one or several cooling bodies 11, which have one or several, preferably vertically extending, cooling ribs or cooling channels for cooling air. One or several fans are arranged on the lower edge of the cooling body 11 in order to conduct air charged with waste heat through the cooling body 11 and to thus transmit the waste heat to the cooling plate 10 through which coolant flows. The cooling body 11 can be formed in one piece directly on the cooling plate 10, or can be attached to it as at least one separate element in a good heat-conducting manner. Alternatively, the at least one fan 12 can also be positioned on the upper edge area of the cooling body 11 and is arranged so that it aspirates the air heated by the electronic components and conducts it through the cooling body 11 or, if not provided, directly along the inside of the cooling plate 10. For improving the air guidance, air guidance vanes 13 can be attached in a suitable arrangement in the interior of the control housing 1, as further shown in FIG. 2A, for achieving the best possible cooling effect. In accordance with FIG. 2A, the cooling guidance vanes 13 are arranged obliquely, for example, in the lower and upper rear corner area of the control housing 1 to assure good air circulation. The cooling plate 10 has an inflow and an outflow connector 10.1 or 10.1′ in its lower edge area.

As represented in FIG. 3, cooling channels extending in a meander shape are formed in the interior of the cooling plate 10, which can be conducted more or less closely to each other, depending on the desired cooling output. As represented in the cross-sectional view in FIG. 4, the design of the cooling channels is provided so that initially groove-like channels are machined from the one flat side of the cooling plate 10 which, for example, forms the back of the rear wall 2, into which one or several cooling lines 10.2 are pressed in order to assure, on the one hand, a good heating contact of the cooling lines 10.2, which are capable of conducting heat, and also secure fastening. The opening of the groove-shaped channel in the direction of the flat side is narrower than its interior, so that the pressed-in cooling line 10.2 is securely held. Protrusions of the cooling line 10.2 on the flat outside of the cooling plate 10 are flattened after the installation, for which the cooling lines 10.2 have a sufficiently thick wall area. Created gaps or unevenness are filled, for example, by a conductive adhesive or the like, and smoothed. In accordance with FIG. 3, the inflow and outflow connectors 10. 1, 10.1′ are arranged near each other in the lower center area of the cooling plate 10, so that a feeding and a removing line can be connected close to each other. The coolant is conducted via the inflow or outflow connectors 10.1, 10.1′ from or to a remote cooling device, for example a recooling arrangement, in order to remove the heat there, or to feed in cooled fluid. Thus, the vicinity of the control housing 1 is barely charged with additional heat via the cooling plate 10, but a high cooling output results in the interior of the control housing 1. Metals with good heat conductivity, in particular copper and/or aluminum, are used for the cooling plate 10, the cooling body 11, as well as the line 10.2.

1. A control housing having four side walls, a front wall and a rear wall, and a cooling device for removing waste heat from installed electronic components, the control housing comprising:
the cooling device having a cooling plate (10) through which a coolant flows which forms a largest portion of the rear wall (2).

2. The control housing in accordance with claim 1, wherein a circumferential edge area (10.4) of the cooling plate (10) is attached to wall sections (2.2) which surround a rear opening (2.1) of the control housing (1) on one of an inside and an outside.

3. The control housing in accordance with claim 2, wherein at least one cooling channel is cut into the cooling plate (10) for conducting coolant and has an inflow connector and an outflow connector (10.1, 10.1′) arranged on an exterior of the rear wall (2).

4. The control housing in accordance with claim 3, wherein at least one cooling body (11) having one of cooling ribs and airflow channels is one of formed as one piece on an inside of the cooling plate (10) facing an interior of the control housing (1) and is applied as a separate part, through which air charged with waste heat flows in the interior of the control housing (1).

5. The control housing in accordance with claim 4, wherein at least one fan (12) is arranged in the interior of the control housing (1) for transporting air charged with waste heat to one of the cooling plate (10) and the cooling body (11).

6. The control housing in accordance with claim 5, wherein a computer (20) with a display field (21) installed in the front wall is received in the control housing (1) which has a fan installed in the computer housing (22) and which is brought into contact with the interior of the control housing for removing the air to one of the cooling plate (10) and the cooling body (11).

7. The control housing in accordance with claim 6, wherein at least one air guidance vane (13) is applied to the interior of the control housing(1), by which the air charged with waste heat is guided one of along the inside of the cooling plate (10) and over the cooling body (11).

8. The control housing in accordance with claim 7, wherein the at least one cooling channel has a line (10.2) installed.

9. The control housing in accordance with claim 8, wherein the line (10.2) is pressed into at least one receiving conduit which is machined from a flat side and extends in a meander shape, and a respective flat side is subsequently flattened out.

10. The control housing in accordance with claim 1, wherein at least one cooling channel is cut into the cooling plate (10) for conducting coolant and has an inflow connector and an outflow connector (10.1, 10.1′) arranged on an exterior of the rear wall (2).

11. The control housing in accordance with claim 1, wherein at least one cooling body (11) having one of cooling ribs and airflow channels is one of formed as one piece on an inside of the cooling plate (10) facing an interior of the control housing (1) and is applied as a separate part, through which air charged with waste heat flows in the interior of the control housing (1).

12. The control housing in accordance with claim 1, wherein at least one fan (12) is arranged in an interior of the control housing (1) for transporting air charged with waste heat to one of the cooling plate (10) and the cooling body (11).

13. The control housing in accordance with claim 12, wherein a computer (20) with a display field (21) installed in the front wall is received in the control housing (1) which has a fan installed in a computer housing (22) and which is brought into contact with the interior of the control housing for removing the air to one of the cooling plate (10) and the cooling body (11).

14. The control housing in accordance with claim 5, wherein at least one air guidance vane (13) is applied to the interior of the control housing (1), by which the air charged with waste heat is guided one of along the inside of the cooling plate (10) and over the cooling body (11).

15. The control housing in accordance with claim 3, wherein the at least one cooling channel has a line (10.2) installed.

16. The control housing in accordance with claim 15, wherein the line (10.2) is pressed into at least one receiving conduit which is machined from a flat side and extends in a meander shape, and a respective flat side is subsequently flattened out.
